(19) United States
(12) Patent Application Publication
(10) Pub. No.: US 2008/0131587 A1
(43) Pub. Date: Jun. 5, 2008

(54) DEPOSITING ORGANIC MATERIAL ONTO AN OLED SUBSTRATE

(76) Inventors: Michael L. Boroson, Rochester, NY (US); Michael Long, Hilton, NY (US); Jeremy M. Grace, Penfield, NY (US); Neil P. Redden, Sodus Point, NY (US); Dustin L. Winters, Webster, NY (US); Thomas W. Palone, Rochester, NY (US)

Correspondence Address: Frank Pincelli;Patent Legal Staff, Eastman Kodak Company, 343 State Street, Rochester, NY, 14650-2201, US

(21) Appl. No.: 11/564,976

(22) Filed: Nov. 30, 2006

(51) Int. Cl. B05D 5/06; B05D 1/32

(52) U.S. Cl. 427/66

(57) ABSTRACT

A method of depositing organic material onto an OLED substrate, comprising: providing a manifold for receiving vaporized organic material, the manifold including an aperture plate having openings, the aperture plate openings being selected to provide beams of vaporized organic material directed to the substrate, such beams having off-axis components; and providing a mask spaced between the OLED substrate and the manifold, the mask having openings that respectively correspond to the aperture plate openings, the mask openings being selected to skim off at least a portion of the off-axis components of the beams.

### FIELD OF THE INVENTION

The present invention relates to the field of physical vapor deposition on an OLED device where a source material is heated to a temperature so as to cause vaporization and form a thin film on a surface of a substrate.

### BACKGROUND OF THE INVENTION

An organic light-emitting diode (OLED) device, also referred to as an organic electroluminescent device, can be constructed by sandwiching two or more organic layers between first and second electrodes.

In single-color OLED devices or displays, also called monochrome OLEDs, these organic layers are not patterned but are formed as continuous layers. In multicolor OLED devices or displays or in full-color OLED displays, organic hole-injecting and hole-transporting layers are formed as continuous layers over and between the first electrodes. A pattern of one or more laterally adjacent organic light-emitting layers is then formed over the continuous hole-injecting and hole-transporting layer. This pattern, and the organic materials used to form the pattern, is selected to provide multicolor or full-color light-emission from a completed and operative OLED display in response to electrical potential signals applied between the first and second electrodes. Unpatterned organic electron-transporting and electron-injecting layers are formed over the patterned light-emitting layers, and one or more second electrodes are provided over this latter organic layer.

Providing a patterned organic light-emitting layer capable of emitting light of two or three different colors, e.g. the primary colors of red (R), green (G), and blue (B), is also referred to as color pixelation, since the pattern is aligned with pixels of an OLED display. The RGB pattern provides a full-color OLED display.

Various processes have been proposed to achieve color pixelation in OLED imaging panels. For example, Tang et al., in commonly assigned U.S. Pat. No. 5,294,869, disclose a process for the fabrication of a multicolor OLED imaging panel using a shadow masking method in which sets of pillars or walls made of electrically insulating materials form an integral part of the device structure. A multicolor organic electroluminescent (“EL”) medium is vapor deposited and patterned by controlling an angular position of a substrate with respect to a deposition vapor stream. The complexity of this process resides in the requirements that the integral shadow mask have multilevel topological features, which can be difficult to produce, and that angular positioning of the substrate with respect to one or more vapor sources must be controlled.

Littman et al., in commonly assigned U.S. Pat. No. 5,688,551, recognized the complexity of the above process, and disclose a method of forming a multicolor organic EL display panel in which a close-spaced deposition technique is used to form a separately colored organic EL medium on a substrate by patternwise transferring the organic EL medium from a donor sheet to the substrate. The donor sheet includes a radiation-absorbing layer which can be unpatterned or which can be prepatterned in correspondence with a pattern of pixels or subpixels on the substrate. The donor sheet must be positioned either in direct contact with or at a controlled distance from the substrate surface to reduce the undesirable effect of divergence of the EL medium vapors issuing from the donor sheet upon heating the radiation-absorbing layer.

In general, positioning an element, such as a donor sheet or a mask, in direct contact with a surface of a substrate can invite problems of abrasion, distortion, or partial lifting of a relatively thin and mechanically fragile organic layer formed previously on the substrate surface. For example, organic hole-injecting and hole-transporting layers can be formed over the substrate, followed by deposition of a first-color pattern. In depositing a second-color pattern, direct contact of a donor sheet or a mask with the first-color pattern can cause abrasion, distortion, or partial lifting of the first-color pattern.

Positioning a donor sheet or a mask at a controlled distance from the substrate surface can require incorporation of spacer elements on the substrate, on the donor sheet or mask, or on both the substrate and the donor sheet. Alternatively, special fixtures may be needed to provide for a controlled spacing between the substrate surface and a donor sheet or mask.

The potential problems or constraints also apply to disclosures by Grande et al. in commonly assigned U.S. Pat. No. 5,851,709, which describes a method for patterning high-resolution organic EL displays, as well as to teachings by Nagayama et al. in U.S. Pat. No. 5,742,129, which discloses the use of shadow masking in manufacturing an organic EL display panel.

The above potential problems or constraints are overcome by disclosures of Tang et al. in commonly assigned U.S. Pat. No. 6,066,357, which teaches methods of making a full-color OLED display. The methods include ink-jet printing of fluorescent dopants selected to produce red, green, or blue light emission from designated subpixels of the display. The dopants are printed sequentially from ink-jet printing compositions over an organic light-emitting layer that contains a host material selected to provide host light emission in a blue spectral region. The dopants diffuse from the dopant layer into the light-emitting layer.

Ink-jet printing of dopants does not require masks, and surfaces of ink-jet print heads do not contact a surface of the organic light-emitting layer. However, the ink-jet printing of dopants is performed under ambient conditions in which oxygen and moisture in the ambient air can result in partial oxidative decomposition of the uniformly deposited organic light-emitting layer containing the host material. Additionally, direct diffusion of a dopant, or subsequent diffusion of a dopant, into the light-emitting layer can cause partial swelling and attendant distortion of the light-emitting layer.

OLED imaging displays can be constructed in the form of passive-matrix devices or active matrix devices. In a passive-matrix OLED display of conventional construction, a plurality of laterally spaced light-transmissive anodes, for example, indium-tin-oxide (ITO) anodes are formed as first electrodes on a light-transmissive substrate, such as a glass substrate. Three or more organic layers are then formed successively by vapor deposition of respective organic materials from respective vapor sources within a chamber held at reduced pressure, typically less than 10⁻³ Torr (1.33×10⁻¹ Pa). A plurality of laterally spaced cathodes is deposited as second electrodes over an uppermost one of the organic layers. The cathodes are oriented at an angle, typically at a right angle, with respect to the anodes. Such conventional passive-matrix OLED displays are operated by applying an electrical potential (also referred to as a drive voltage) between an individual row (cathode) and, sequentially, each column (anode). When a cathode is biased negatively with respect to an anode, light is emitted from a pixel defined by an overlap area of the cathode and the anode, and emitted light reaches an observer through the anode and the substrate.

In an active-matrix OLED display, an array of sets of thin-film transistors (TFTs) is provided on a light-transmissive substrate, such as a glass substrate. Each TFT is connected to a corresponding light-transmissive anode pad, which can be made, for example, of indium-tin-oxide (ITO). Three or more organic layers are then formed successively by vapor deposition in a manner substantially equivalent to the construction of a passive-matrix OLED display. A common cathode is deposited as a second electrode over the uppermost of the organic layers. The construction and function of an active matrix OLED display is described in commonly assigned U.S. Pat. No. 5,550,066.

In order to provide a multicolor or a full-color (red, green, and blue subpixels) passive-matrix or active-matrix OLED display, color pixelation of at least portions of an organic light-emitting layer can be used. Color pixelation of OLED displays can be achieved through various methods as detailed above. One common method of color pixelation integrates the use of one or more vapor sources and a precision shadow mask temporarily fixed in reference to a device substrate. Organic light-emitting material is sublimed from a source (or from multiple sources) and deposited on the OLED substrate through the open areas of the aligned precision shadow mask as a light-emitting layer.

This physical vapor deposition (PVD) for OLED production is achieved in vacuum through the use of a heated vapor source of vaporizable organic OLED material. The organic material is heated to attain sufficient vapor pressure to effect efficient sublimation, creating a vaporous organic material plume that travels to and deposits on an OLED substrate. A variety of vapor sources based on different operating principles exist, including the so-called point sources (heated small cross-sectional-area sources) and linear sources (elongated sources of large cross-sectional area). Multiple mask-substrate alignments and vapor depositions are used to deposit a pattern of differing light-emitting layers on desired substrate pixel or subpixel areas creating, for example, a desired pattern of red, green, and blue pixels or subpixels on an OLED substrate. In this method, which is commonly used in OLED production, much of the vaporized material present in the vaporous material plume is not deposited onto desired areas of the substrate, but onto various vacuum chamber walls, shielding, and precision shadow masks. This leads to poor material utilization factors and consequently high materials cost.

Although precision shadow-masking is a feasible method for OLED production, it also presents many potential complications to display manufacturing. First, care must be taken in positioning these masks onto and removing them from a device substrate to avoid physical damage to OLED devices. Second, when vacuum depositing on large-area substrates, it is difficult to keep shadow masks in intimate contact in all areas of the substrate, which can lead to unfocussed depositions or mask-induced physical damage to the substrate. Third, when vacuum-depositing three colored regions at different locations on the substrate, three sets of precision shadow masks may be needed and can cause unwanted delays in OLED production. Fourth, keeping mask-to-substrate precision alignment over the entirety of large substrates is very difficult for several reasons, including mask-substrate thermal expansion mismatches, small pixel pitches, and mask fabrication limitations. Also, when vacuum depositing multiple substrates during a single vacuum pump-down cycle, material residue can build up on shadow masks and eventually cause defects to form in the pixels being deposited.

Thus, there is a continuing need for improvement in OLED device manufacturing.

### SUMMARY OF THE INVENTION

It is therefore an object of the present invention to provide an improved method of OLED device manufacturing that reduces problems encountered with precision shadow-mask methods.

This object is achieved by a method of depositing organic material onto an OLED substrate, comprising:

a) providing a manifold for receiving vaporized organic material, the manifold including an aperture plate having openings, the aperture plate openings being selected to provide beams of vaporized organic material directed to the substrate, such beams having off-axis components; and

b) providing a mask spaced between the OLED substrate and the manifold, the mask having openings that respectively correspond to aperture plate openings, the mask openings being selected to skim off at least a portion of the off-axis components of the beams.

### ADVANTAGES

It is an advantage of this invention that the need for a precision two-dimensional mask is eliminated in the coating process, and that a linear mask, which is easier to fabricate, can be used. It is a further advantage of this invention that such a linear mask can have a major length much larger than practicable for a two-dimensional large-area mask, thus allowing the fabrication of larger OLED displays. It is a further advantage of this invention that it allows higher material utilization and less waste.

### BRIEF DESCRIPTION OF THE DRAWINGS

FIG. 1A shows an embodiment of a manifold with aperture plate openings that can be used in accordance with the method of this invention;

FIG. 1B shows a cross-sectional view of the manifold of FIG. 1A and a beam of vaporized organic material provided by the manifold;

FIG. 1C shows a cross-sectional view of one embodiment of an aperture plate opening;

FIG. 2A shows an embodiment of a mask having openings corresponding to the aperture plate openings of FIG. 1A, which can be used in accordance with the method of this invention;

FIG. 2B shows another embodiment of a mask having openings corresponding to the aperture plate openings of FIG. 1A, which can be used in accordance with the method of this invention;

FIG. 3A shows a cross-sectional view of the manifold of FIG. 1A providing beams of vaporized organic material to an OLED substrate, and the mask of FIG. 2B spaced between the substrate and manifold in accordance with the method of this invention;

FIG. 3B shows another cross-sectional view of the apparatus of FIG. 3A;

FIG. 3C shows another cross-sectional view of a portion of the apparatus of FIG. 3A in greater detail;

FIGS. 4A and 4B show additional embodiments of a manifold with aperture plate openings that can be used in accordance with the method of this invention;

FIG. 5 shows the manifold of FIG. 1A and the mask of FIG. 1C with a non-precision mask in accordance with the method of this invention; and

FIG. 6 shows a block diagram of one embodiment of the method of this invention.

### DETAILED DESCRIPTION OF THE INVENTION

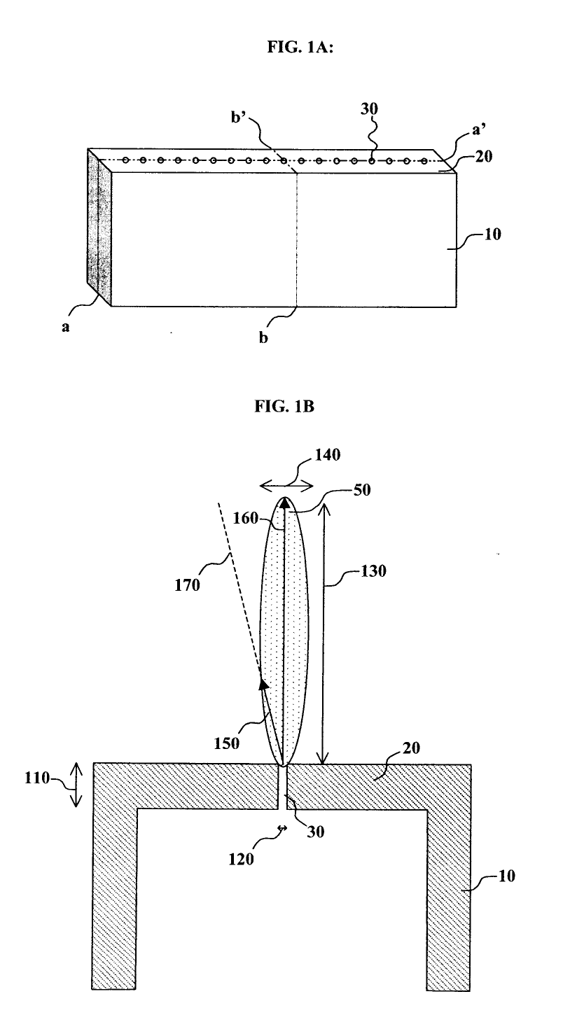

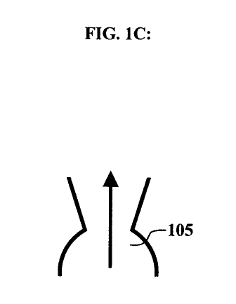

Turning now to FIG. 1A, there is shown one embodiment of a manifold with aperture plate openings that can be used in accordance with the method of this invention. Manifold 10 includes aperture plate 20, which has openings 30. As will be shown, openings 30 are selected so as to provide beams of vaporized organic material directed to a substrate. Manifold 10 can receive vaporized organic material that is provided by a variety of vaporization methods, such as those disclosed by Grace et al. in US Publication No. 2006/0099345, the contents of which are incorporated by reference. In one desirable embodiment, manifold 10 is an elongated manifold. That is, the length along section a-a′ is significantly greater than the width along section b-b′.

Manifold 10 and openings 30 are constructed so as to provide a directed beam of vaporized organic material under conditions of viscous flow or molecular flow. Turning now to FIG. 1B, there is shown one cross-sectional view of manifold 10 and a beam of vaporized organic material that it can provide. Aperture plate opening 30, in this embodiment, is a uniform-diameter tube and has a length 110 (L) and a diameter 120 (D). The relative dimensions of aperture plate opening 30 determine the angular distribution of beam 50 of vaporized organic material. For example, in the molecular flow regime, where transport through an orifice is by molecular effusion, if the ratio of length 110 to diameter 120 (i.e. the ratio L/D) is near zero, the distribution of vaporized organic material will approximate a cosine distribution, and will not be properly described as a beam. It is necessary for length 110 to be significantly larger than diameter 120 to produce a beam. As described by Valyi in “Atom and Ion Sources”, John Wiley & Sons, 1977, pg. 86, the ratio of length 110 to diameter 120 must be at least 5:1 to produce even a moderately directed beam. For a highly directed beam, it is desirable that the ratio of length to diameter be at least 100:1 or greater.

Beam 50 has on-axis components (e.g. vector 160) and off-axis components (e.g. vector 150). It will be understood that FIG. 1B shows the angular distribution of organic material, and not the actual shape of the beam. For example, the intensity of the off-axis component represented by vector 150 is significantly less than the intensity of vector 160, which is the on-axis component of beam 50. However, this means that there is some deposition of material in off-axis direction 170. As such, length 130 and width 140 are useful for comparing the directionality of the beam and determining a peaking factor. A peaking factor, as defined by Jones, et al., J. Appl. Physics, 40 (1), p. 4641-4649 (1969), can be expressed as the ratio of the on-axis intensity of the beamed source (that is, along vector 160) to the on-axis intensity from an ideal thin-walled source (i.e. L/D<<1) emitting at the same total leak rate. It is defined as:

$$χ = \frac{J ( 0 ) / 1}{{J}^{*} ( 0 ) / {1}^{*}} = ( π / 1 ) J ( 0 ) \text{)} \qquad ( 1 )$$

where J(θ) represents the flux at polar angle θ, l represents the leak rate, and the asterisk represents a cosine emitter, that is, J*(θ)=l*(cos θ/90 )

In an effort to provide improved understanding of forming a directed beam of a gas flowing though a nozzle under conditions of viscous flow or molecular flow, pertinent sections of “Handbook of Thin Film Technology”, edited by Leon I. Maissel and Reinhard Glang, published by McGraw Hill Book Company in 1970 and “Foundations of Vacuum Science and Technology edited by James M. Lafferty, published by John Wiley & Sons, Inc. are referenced.

If a gas is flowing through a narrow tube, it encounters resistance at the walls of the tube. Thus, gas layers at and adjacent to the walls are slowed down, causing viscous flow. A viscosity coefficient η results from internal friction caused by intermolecular collisions. This viscosity coefficient η is given by

$$η = \frac{2 f}{π {σ}^{2}} {( \frac{{mk}_{B} T}{π} )}^{1 / 2} \qquad ( 2 )$$

where f is a factor between 0.3 and 0.5 depending on the assumed model of molecular interaction. For most gases, f=0.499 is a good assumption. σ is the molecular diameter; m is the mass of a gas molecule; κ_{B} is the Boltzmann constant; and T is the temperature of the gas, given in Kelvin (K).

Specifically, for a straight cylindrical tube of length l and a radius r having an inert gas flowing through it, a viscous flow microscopic flow rate Q_{visc} can be given by

$${Q}_{visc} = \frac{π {r}^{4}}{81 η} {p}_{avg} ( {p}_{2} - {p}_{1} ) \qquad ( 3 )$$

wherein p_{avg} is the average pressure in the tube, and p₂ and p₁ are the pressures at opposing ends of the tube.

The mean free path of a gas λ is given by

$$λ = \frac{{k}_{B} T}{\sqrt{2} π {σ}^{2} P} = \frac{1}{\sqrt{2} π n {σ}^{2}} \qquad ( 4 )$$

where σ is the molecular diameter, n is the number of molecules per unit volume and P is the gas pressure.

When gas flows through a tube of diameter d there are in general three flow regimes that can be used to characterize the flow: free molecular flow, continuum or viscous flow, and transitional flow. Knudsen's number Kn is used to characterize the flow regime and is given by

Kn=λ/d (5).

When Kn>0.5, the flow is in the free molecular flow regime. Here gas dynamics are dominated by molecular collisions with the walls of the tube or vessel. Gas molecules flow through the tube by successive collisions with the walls until experiencing a final collision, which ejects them through the opening. Depending on the length-to-diameter ratio of the tube, the angular distribution of emitted molecules can range from a cosine theta distribution for zero length to a heavily beamed profile for large length-to-diameter ratios (see Lafferty for details). Even in the case of the heavily beamed profile, there is a significant component of the emitted flux at non-zero angles to the axis of the tube. The molecular flow regime is useful in this invention.

When Kn<0.01, the flow is in the viscous flow regime and is dominated by intermolecular collisions. Here the mean free path of a gas molecule is small compared to the diameter of the tube, and intermolecular collisions are much more frequent than wall collisions. When operating in the viscous flow regime, gas coming out of the tube orifice usually flows smoothly in streamlines generally parallel to the walls of the orifice and can be highly directed in the case of large length-to-diameter ratios. Such flows are often referred to as “jets” in the art, but the term “beams” will also be used herein. The viscous flow regime is useful in this invention.

When 0.01<Kn<0.5, the flow is in the transitional flow regime in which both molecular collisions with the wall and intermolecular collisions influence flow characteristics of the gas. The directionality of beams is severely hampered in the transitional flow regime, and thus the transitional flow regime is to be avoided in the practice of this invention.

For certain vaporizable materials, the vapor pressure at useful temperatures is low enough that it is difficult to attain viscous flow for small openings, such as would be useful in producing pixilated OLED displays. In such cases, an additional carrier gas (for example, an inert gas such as nitrogen or argon) can be added to the vaporized material to produce the viscous flow.

The vapor pressure p* of a gas can be approximated from the relationship

Log p*=A/T+B+C Log T (6)

where A, B, and C are constants. The vapor pressure of tris(8-quinolinolato)aluminum (Alq) has been measured to vary from 0.024-0.573 Torr from 250-350° C. The best fit coefficients were found to be A=−2245.996, B=−21.714, and C=8.973. The mean free path for Alq varies from 0.5-0.0254 mm at the vapor pressure over the temperature range 250-350° C. Thus the vapor pressure of Alq alone is insufficient to produce viscous flow in a circular nozzle structure with a 100 μm tube diameter over the temperature range 250-350° C. A vapor pressure of approximately 15 Torr will be required to get into the viscous flow regime for Alq and this tube diameter.

Thus, with knowledge of the properties of materials, one can select the aperture plate openings and the pressure of vaporized material in the manifold to provide molecular flow. Alternatively, one can select the aperture plate openings and the pressure of vaporized material in the manifold, with a carrier gas added to the vaporized material if necessary, to provide viscous flow. The ratio of length to diameter of the aperture plate openings can be selected to provide beams of the vaporized organic material.

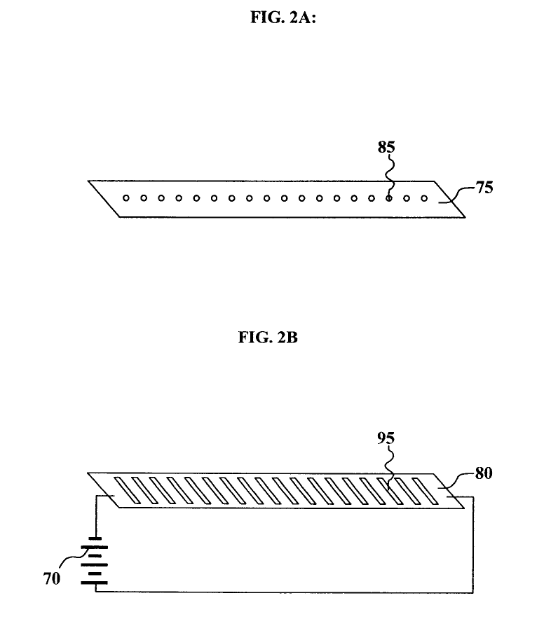

Turning now to FIG. 1C, there is shown a cross-sectional view of another embodiment of an aperture plate opening. Aperture plate opening 105 has a convergent-divergent structure, also known as a de Laval nozzle, which can be a useful opening structure in the viscous flow regime for forming a narrow jet. Turning now to FIG. 2A, there is shown one embodiment of a mask having openings corresponding to the aperture plate openings of FIG. 1A, which can be used in accordance with the method of this invention. Mask 75 has openings 85 corresponding to aperture plate openings 30 of manifold 10. The beams of vaporized material provided by manifold 10 are selected to be largely on the axis of the beam, but have some off-axis components. Openings 85 in mask 75 are selected to skim off at least a portion of the off-axis components of the beams. Mask 75 is a linear mask, that is, it only has openings in a one dimensional array.

Turning now to FIG. 2B, there is shown another embodiment of a mask having openings corresponding to the aperture plate openings of FIG. 1A, which can be used in accordance with the method of this invention. Mask 80 has openings 95 corresponding to aperture plate openings 30 of manifold 10. Openings 95 in mask 80 are selected to skim off at least a portion of the off-axis components of the beams. In particular, openings 95 will skim off the off-axis components in one direction, as will be seen.

Because mask 80 can skim off a portion of off-axis components from manifold 10, it is likely that condensed off-axis material will build up on the mask. A potential source 70, e.g. a battery or other energy source, can be used to heat mask 80 to remove condensed off-axis organic material from the mask. Such heating can be continuous during operation, or with the use of a switch, heat can be applied to the mask at selected times, e.g. between coating OLED substrates. Removing condensed off-axis material from mask 80 can also be done in other ways, for example solvent cleaning, plasma cleaning, or laser ablation.

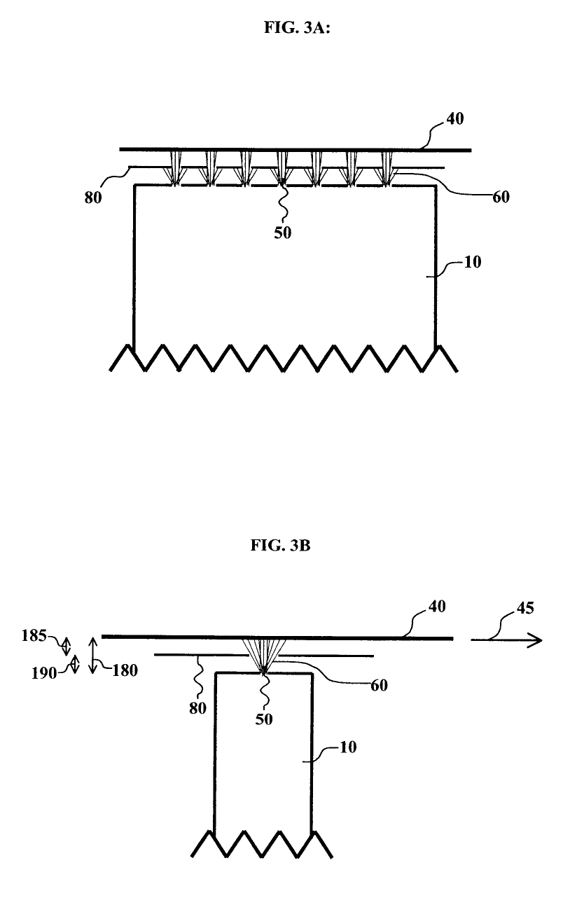

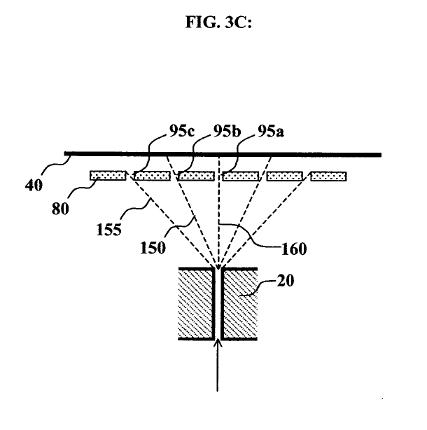

Turning now to FIG. 3A, there is shown one cross-sectional view of the manifold of FIG. 1A providing beams of vaporized organic material to an OLED substrate, and the mask of FIG. 2B spaced between the substrate and manifold in accordance with the method of this invention. This view is along cross-section a-a′ of FIG. 1A. Aperture plate openings 30 of manifold 10 are selected as described above to provide beams of vaporized organic material 50 in the molecular flow regime or the viscous flow regime directed to OLED substrate 40 so as to deposit organic material on OLED substrate 40. Such beams 50 have off-axis components 60, which can cause vaporized organic material to be deposited over too widespread an area on OLED substrate 40. Mask 80 is provided spaced between OLED substrate 40 and manifold 10. Openings 95 of mask 80 correspond to aperture plate openings 30 and are selected to skim off at least a portion of off-axis components 60 of beam 50.

Turning now to FIG. 3B, there is shown another cross-sectional view of the apparatus of FIG. 3A. This view is along cross-section b-b′ of FIG. 1A. In this direction, mask 80 does not remove the off-axis components of the beams, or removes less of them than in the direction shown in FIG. 3A. In this embodiment, relative motion between OLED substrate 40 and manifold 10 in direction 45 will deposit a series of stripes of organic material on substrate 40. Alternatively, the beams of vaporized material can be selectively turned on and off to form a pattern, e.g. a two-dimensional array of pixels as known in the art, on OLED substrate 40.

Turning now to FIG. 3C, there is shown another cross-sectional view of a portion of the apparatus of FIG. 3A in greater detail. A portion of aperture plate 20 is shown to illustrate a single opening. Vaporized organic material is emitted from aperture plate 20 to substrate 40. On-axis components 160 pass through opening 95a of mask 80 and are deposited on OLED substrate 40. Some portions of off-axis components 150 can also pass through mask 80 to be deposited on OLED substrate 40 in positions formed by adjacent mask openings of mask 80, e.g. via opening 95b. However, as shown, off-axis portions 155 at other angles can be prevented from passing through mask 80, e.g. via opening 95c. The position of mask 80 relative to aperture plate 20 and OLED substrate 40, the thickness of mask 80, and the size and geometry of the openings of mask 80 can be selected to determine which, if any, portions of off-axis components will be deposited on OLED substrate 40.

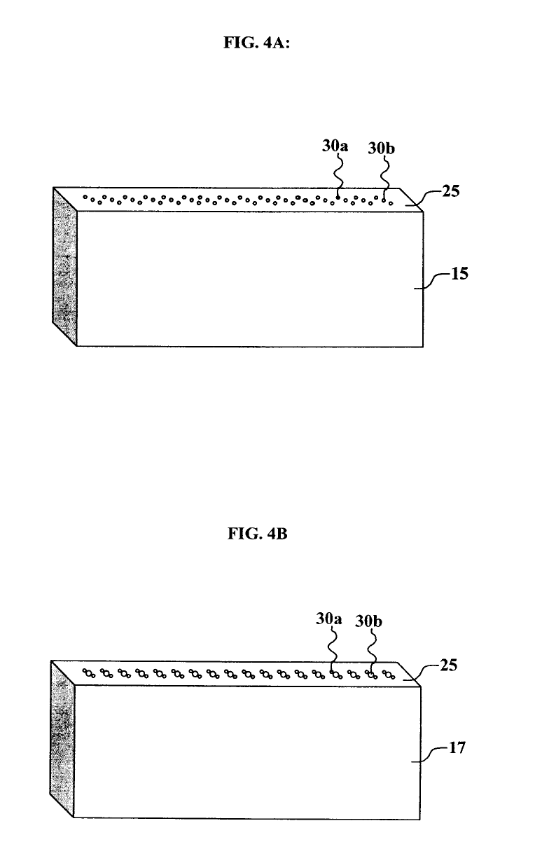

Turning now to FIG. 4, there is shown another embodiment of a manifold with aperture plate openings that can be used in accordance with the method of this invention. Manifold 15 includes aperture plate 25, which has openings 30. Instead of a single line of aperture plate openings as in manifold 10, manifold 15 has several lines of openings 30 that are slightly offset, e.g. outer aperture plate openings 30a and center aperture plate openings 30b. Such an arrangement of aperture plate openings allows for producing a tighter spaced array than a single line of aperture plate openings. FIG. 4B shows a variation of this embodiment wherein outer aperture plate openings 30a of manifold 17 are smaller than center aperture plate openings 30b. Such an arrangement allows for a beam that has less material near the edge, and thus can have smaller off-axis components to be skimmed off by a mask.

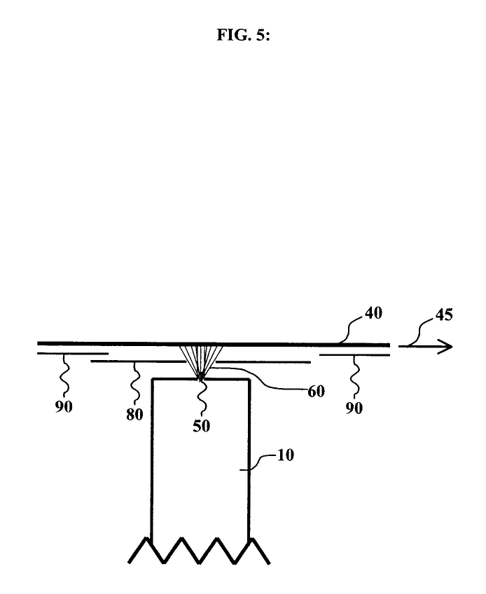

Turning now to FIG. 5, there is shown the manifold of FIG. 1A providing beams of vaporized organic material to an OLED substrate, and the mask of FIG. 2B spaced between the substrate and manifold, and a non-precision mask spaced between the mask and the substrate in accordance with the method of this invention. Non-precision mask 90 has at least one opening. Substrate 40 and non-precision mask 90 move in direction 45 relative to manifold 10 and mask 80, which creates a series of stripes of deposited organic material on substrate 45. Non-precision mask 90 prevents OLED material from being deposited in undesired regions on OLED substrate 40. Undesired regions for organic material can include, for example, electrical contacts, the sealing region, and other non-emitting areas of substrate 40.

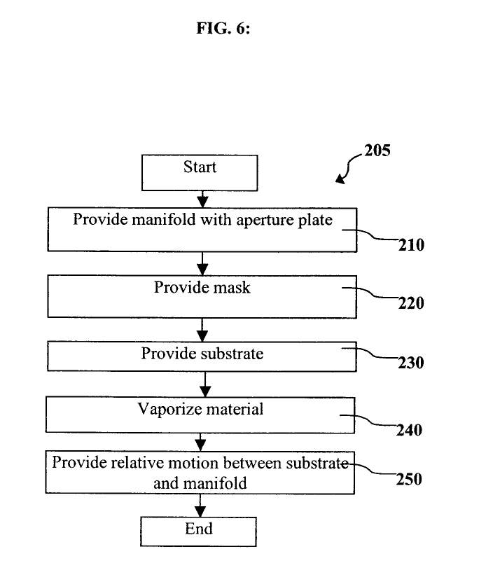

Turning now to FIG. 6, and referring also to FIG. 3B, there is shown a block diagram of one embodiment of the method 205 of this invention for depositing organic material onto an OLED substrate. At the start, a manifold 10 is provided with an aperture plate 20 with aperture plate openings 30 (Step 210). Then a mask 80 is provided with openings 95 (Step 220) and an OLED substrate 40 is provided (Step 230). Mask 80 is spaced between manifold 10 and OLED substrate 40. Vaporized material is then provided to manifold 10 to provide beams of vaporized organic material 50 directed toward OLED substrate 40 (Step 240), and mask openings 95 skim off at least a portion of the off-axis components of the beams. Relative motion is provided between OLED substrate 40 and manifold 10 so that stripes of organic material will be deposited onto OLED substrate 40 (Step 250).

OLED substrates useful in this invention can be organic solids, inorganic solids, or a combination of organic and inorganic solids. The substrate can be rigid or flexible and can be processed as separate individual pieces, such as sheets or wafers, or as a continuous roll. Typical substrate materials include glass, plastic, metal, ceramic, semiconductor, metal oxide, semiconductor oxide, semiconductor nitride, or combinations thereof. The substrate can be a homogeneous mixture of materials, a composite of materials, or multiple layers of materials. The substrate can be an active-matrix low-temperature polysilicon or amorphous-silicon TFT substrate. The substrate can either be light transmissive or opaque, depending on the intended direction of light emission. The light transmissive property is desirable for viewing the EL emission through the substrate. Transparent glass or plastic are commonly employed in such cases. For applications where the EL emission is viewed through the top electrode, the transmissive characteristic of the bottom support is immaterial, and therefore can be light transmissive, light absorbing or light reflective. Substrates for use in this case include, but are not limited to, glass, plastic, semiconductor materials, ceramics, and circuit board materials, or any others commonly used in the formation of OLED devices, which can be either passive-matrix devices or active-matrix devices.

Organic materials that can be deposited by the method of this invention include hole-transporting materials, light-emitting materials, and electron-transporting materials. Hole-transporting materials are well known to include compounds such as an aromatic tertiary amine, where the latter is understood to be a compound containing at least one trivalent nitrogen atom that is bonded only to carbon atoms, at least one of which is a member of an aromatic ring. In one form the aromatic tertiary amine can be an arylamine, such as a monoarylamine, diarylamine, triarylamine, or a polymeric arylamine. Exemplary monomeric triarylamines are illustrated by Klupfel et al. in U.S. Pat. No. 3,180,730. Other suitable triarylamines substituted with one or more vinyl radicals and/or comprising at least one active hydrogen-containing group are disclosed by Brantley et al. in U.S. Pat. Nos. 3,567,450 and 3,658,520.

A more preferred class of aromatic tertiary amines are those which include at least two aromatic tertiary amine moieties as described in U.S. Pat. Nos. 4,720,432 and 5,061,569. Such compounds include those represented by structural Formula A.

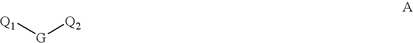

wherein:

Q₁ and Q₂ are independently selected aromatic tertiary amine moieties; and

G is a linking group such as an arylene, cycloalkylene, or alkylene group of a carbon to carbon bond.

In one embodiment, at least one of Q1 or Q2 contains a polycyclic fused ring structure, e.g., a naphthalene. When G is an aryl group, it is conveniently a phenylene, biphenylene, or naphthalene moiety.

A useful class of triarylamines satisfying structural Formula A and containing two triarylamine moieties is represented by structural Formula B.

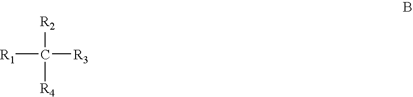

where:

R₁ and R₂ each independently represent a hydrogen atom, an aryl group, or an alkyl group or R₁ and R₂ together represent the atoms completing a cycloalkyl group; and

R₃ and R₄ each independently represent an aryl group, which is in turn substituted with a diaryl substituted amino group, as indicated by structural Formula C.

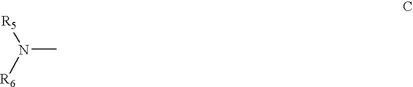

wherein R₅ and R₆ are independently selected aryl groups. In one embodiment, at least one of R₅ or R₆ contains a polycyclic fused ring structure, e.g., a naphthalene.

Another class of aromatic tertiary amines are the tetraaryldiamines. Desirable tetraaryldiamines include two diarylamino groups, such as indicated by Formula C, linked through an arylene group. Useful tetraaryldiamines include those represented by Formula D.

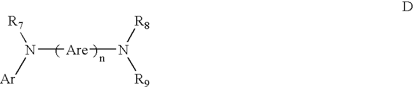

wherein:

each Are is an independently selected arylene group, such as a phenylene or anthracene moiety;

n is an integer of from 1 to 4; and

Ar, R₇, R₈, and R₉ are independently selected aryl groups.

In a typical embodiment, at least one of Ar, R₇, R₈, and R₉ is a polycyclic fused ring structure, e.g., a naphthalene.

The various alkyl, alkylene, aryl, and arylene moieties of the foregoing structural Formulae A, B, C, D, can each in turn be substituted. Typical substituents include alkyl groups, alkoxy groups, aryl groups, aryloxy groups, and halogens such as fluoride, chloride, and bromide. The various alkyl and alkylene moieties typically contain from 1 to about 6 carbon atoms. The cycloalkyl moieties can contain from 3 to about 10 carbon atoms, but typically contain five, six, or seven carbon atoms—e.g., cyclopentyl, cyclohexyl, and cycloheptyl ring structures. The aryl and arylene moieties are usually phenyl and phenylene moieties.

Another class of useful hole-transporting materials includes polycyclic aromatic compounds as described in EP 1 009 041. In addition, polymeric hole-transporting materials can be used such as poly(N-vinylcarbazole) (PVK), polythiophenes, polypyrrole, polyaniline, and copolymers such as poly(3,4-ethylenedioxythiophene)/poly(4-styrenesulfonate) also called PEDOT/PSS.

Light-emitting materials produce light in response to hole-electron recombination and are commonly disposed over hole-transporting material. Useful organic light-emitting materials are well known. As more fully described in U.S. Pat. Nos. 4,769,292 and 5,935,721, the light-emitting layers of an OLED element comprise a luminescent or fluorescent material where electroluminescence is produced as a result of electron-hole pair recombination in this region. The light-emitting layers can be comprised of a single material, but more commonly include a host material doped with a guest compound or dopant where light emission comes primarily from the dopant. The dopant is selected to produce color light having a particular spectrum. The host materials in the light-emitting layers can be an electron-transporting material, as defined below, a hole-transporting material, as defined above, or another material that supports hole-electron recombination. The dopant is usually chosen from highly fluorescent dyes, but phosphorescent compounds, e.g., transition metal complexes as described in WO 98/55561, WO 00/18851, WO 00/57676, and WO 00/70655 are also useful. Dopants are typically coated as 0.01 to 10% by weight into the host material.

Host and emitting molecules known to be of use include, but are not limited to, those disclosed in U.S. Pat. Nos. 4,768,292; 5,141,671; 5,150,006; 5,151,629; 5,294,870; 5,405,709; 5,484,922; 5,593,788; 5,645,948; 5,683,823; 5,755,999; 5,928,802; 5,935,720; 5,935,721; and 6,020,078.

Metal complexes of 8-hydroxyquinoline and similar derivatives (Formula E) constitute one class of useful host materials capable of supporting electroluminescence, and are particularly suitable for light emission of wavelengths longer than 500 nm, e.g., green, yellow, orange, and red.

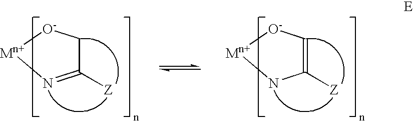

wherein:

M represents a metal;

n is an integer of from 1 to 3; and

Z independently in each occurrence represents the atoms completing a nucleus having at least two fused aromatic rings.

From the foregoing it is apparent that the metal can be a monovalent, divalent, or trivalent metal. The metal can, for example, be an alkali metal, such as lithium, sodium, or potassium; an alkaline earth metal, such as magnesium or calcium; or an earth metal, such as boron or aluminum. Generally any monovalent, divalent, or trivalent metal known to be a useful chelating metal can be employed.

Z completes a heterocyclic nucleus containing at least two fused aromatic rings, at least one of which is an azole or azine ring. Additional rings, including both aliphatic and aromatic rings, can be fused with the two required rings, if required. To avoid adding molecular bulk without improving on function the number of ring atoms is usually maintained at 18 or less.

The host material in a light-emitting layer can be an anthracene derivative having hydrocarbon or substituted hydrocarbon substituents at the 9 and 10 positions. For example, derivatives of 9,10-di-(2-naphthyl)anthracene constitute one class of useful host materials capable of supporting electroluminescence, and are particularly suitable for light emission of wavelengths longer than 400 nm, e.g., blue, green, yellow, orange or red.

Benzazole derivatives constitute another class of useful host materials capable of supporting electroluminescence, and are particularly suitable for light emission of wavelengths longer than 400 nm, e.g., blue, green, yellow, orange or red. An example of a useful benzazole is 2,2′,2″-(1,3,5-phenylene)tris[1-phenyl-1H-benzimidazole].

Desirable fluorescent dopants include perylene or derivatives of perylene, derivatives of anthracene, tetracene, xanthene, rubrene, coumarin, rhodamine, quinacridone, dicyanomethylenepyran compounds, thiopyran compounds, polymethine compounds, pyrilium and thiapyrilium compounds, derivatives of distryrylbenzene or distyrylbiphenyl, bis(azinyl)methane boron complex compounds, and carbostyryl compounds.

Other organic emissive materials can be polymeric substances, e.g. polyphenylenevinylene derivatives, dialkoxy-polyphenylenevinylenes, poly-para-phenylene derivatives, and polyfluorene derivatives, as taught by Wolk et al. in commonly assigned U.S. Pat. No. 6,194,119 B1 and references cited therein.

Preferred electron-transporting materials for use in OLED devices are metal chelated oxinoid compounds, including chelates of oxine itself (also commonly referred to as 8-quinolinol or 8-hydroxyquinoline). Such compounds help to inject and transport electrons and exhibit both high levels of performance and are readily fabricated in the form of thin films. Exemplary of contemplated oxinoid compounds are those satisfying structural Formula E, previously described.

Other electron-transporting materials include various butadiene derivatives as disclosed in U.S. Pat. No. 4,356,429 and various heterocyclic optical brighteners as described in U.S. Pat. No. 4,539,507. Benzazoles satisfying structural Formula G are also useful electron-transporting materials. Other electron-transporting materials can be polymeric substances, e.g. polyphenylenevinylene derivatives, poly-para-phenylene derivatives, polyfluorene derivatives, polythiophenes, polyacetylenes, and other conductive polymeric organic materials.

The invention has been described in detail with particular reference to certain preferred embodiments thereof, but it will be understood that variations and modifications can be effected within the spirit and scope of the invention.

### PARTS LIST

10 manifold
15 manifold
17 manifold
20 aperture plate
25 aperture plate
30 openings
30a openings
30b openings
40 OLED substrate
45 direction
50 beam of vaporized organic material
60 off-axis components
70 potential source
75 mask
80 mask
85 openings
90 non-precision mask
95 openings
95a opening
95b opening
95c opening
105 convergent-divergent opening
110 length
120 diameter
130 length
140 width
150 off-axis component vector
155 off-axis component
160 on-axis component vector
170 direction
205 method
210 block
220 block
230 block
240 block
250 block

What is claimed is:

1. A method of depositing organic material onto an OLED substrate, comprising:
a) providing a manifold for receiving vaporized organic material, the manifold including an aperture plate having openings, the aperture plate openings being selected to provide beams of vaporized organic material directed to the substrate, such beams having off-axis components; and
b) providing a mask spaced between the OLED substrate and the manifold, the mask having openings that respectively correspond to aperture plate openings, the mask openings being selected to skim off at least a portion of the off-axis components of the beams.

2. The method of claim 1 wherein the aperture plate openings and pressure of vaporized material in the manifold are selected to provide molecular flow or viscous flow and the mask position and mask openings are selected so that portions of the off-axis components will be deposited on the OLED substrate in positions formed by adjacent mask openings.

3. The method of claim 2 wherein the aperture plate openings and pressure of vaporized material in the manifold are selected to provide molecular flow.

4. The method of claim 3 wherein the ratio of length to diameter of each aperture plate opening is at least 5:1.

5. The method of claim 4 wherein the ratio of length to diameter of each aperture plate opening is at least 100:1.

6. The method of claim 2 wherein the aperture plate openings and the pressure of vaporized material in the manifold are selected to provide viscous flow.

7. The method of claim 2 wherein a carrier gas is added to the vaporized material and the aperture plate openings and the pressure of carrier g in the manifold are selected to provide viscous flow.

8. The method of claim 6 wherein the ratio of length to diameter of each aperture plate opening is at least 5:1.

9. The method of claim 8 wherein the ratio of length to diameter of each aperture plate opening is at least 100:1.

10. The method of claim 6 wherein the aperture plate openings have a convergent-divergent structure.

11. The method of claim 1 wherein the beams of vaporized organic material are selectively turned on and off to form a pattern on the OLED substrate.

12. The method of claim 1 further including heating the mask to remove condensed off-axis organic material from the mask.

13. The method of claim 12 wherein heat is applied to the mask between coating OLED substrates.

14. The method of claim 1 further including a non-precision mask having at least one opening that prevents organic material from being deposited in undesired regions on the OLED substrate.

15. The method of claim 1 wherein the mask is a linear mask.

16. A method of depositing stripes of organic material onto an OLED substrate, comprising:
a) providing an elongated manifold for receiving vaporized organic material, the manifold including an aperture plate having openings, the aperture plate openings being selected to provide beams of vaporized organic material directed to the substrate, such beams having off-axis components;
b) providing a mask spaced between the OLED substrate and the manifold, the mask having openings that respectively correspond to aperture plate openings, the mask openings being selected to skim off at least a portion of the off-axis components of the beams; and
c) providing relative motion between the OLED substrate and the elongated manifold so that stripes of organic material will be deposited onto the OLED substrate.

17. The method of claim 16 wherein the aperture plate openings and pressure of vaporized material in the manifold are selected to provide molecular flow or viscous flow and the mask position and mask openings are selected so that portions of the off-axis components will be deposited on the OLED substrate in positions formed by adjacent mask openings.

18. The method of claim 17 wherein the aperture plate openings and the pressure of vaporized material in the manifold are selected to provide molecular flow.

19. The method of claim 18 wherein the ratio of length to diameter of each aperture plate opening is at least 5:1.

20. The method of claim 19 wherein the ratio of length to diameter of each aperture plate opening is at least 100:1.

21. The method of claim 16 wherein a carrier gas is added to the vaporized material and the aperture plate openings and the pressure of vaporized material in the manifold are selected to provide viscous flow.

22. The method of claim 17 wherein a carrier gas is added to the vaporized material to produce viscous flow.

23. The method of claim 21 wherein the ratio of length to diameter of each aperture plate opening is at least 5:1.

24. The method of claim 23 wherein the ratio of length to diameter of each aperture plate opening is at least 100:1.

25. The method of claim 21 wherein the aperture plate openings have a convergent-divergent structure.

26. The method of claim 16 wherein the beams of vaporized organic material are selectively turned on and off to form a pattern on the OLED substrate.

27. The method of claim 16 further including heating the mask to remove condensed off-axis organic material from the mask.

28. The method of claim 27 wherein heat is applied to the mask between coating OLED substrates.

29. The method of claim 16 further including a non-precision mask having at least one opening that prevents organic material from being deposited in undesired regions on the OLED substrate.

30. The method of claim 16 wherein the mask is a linear mask.

31. The method of claim 16 wherein the aperture plate openings have a convergent-divergent structure.
